(19) United States
(12) Patent Application Publication
(10) Pub. No.: US 2008/0278061 A1
(43) Pub. Date: Nov. 13, 2008

(54) Light Emitting Diode Module

(75) Inventors: Marc Andre De Samber, Eindhoven (NL); Christoph Gerard August Hoelen, Eindhoven (NL); Eric Cornelis Egbertus Van Grunsven, Eindhoven (NL); Koen Van Os, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/570,906

(22) PCT Filed: Jun. 23, 2005
(86) PCT No.: PCT/IB2005/052068

§ 371 Date: Dec. 19, 2006

(30) Foreign Application Priority Data
Jun. 29, 2004 (EP) 04103042.0

(51) Int. Cl. H01L 33/00

(52) U.S. Cl. 313/498

(57) ABSTRACT

The present invention relates to a LED module (10) comprising a substrate (12), at least one LED chip (20) mounted on a first side of said substrate, and an optical element (21) covering the LED chip(s) (20). The substrate (12) is further provided with at least one via channel (22) extending from the first side of the substrate to a second opposite side of the substrate, whereby the via channel(s) is provided with conducting means for electrically connecting the at least one LED chip (20) to a control circuit (32). By providing the substrate with via channels with conducting means, the control circuit may be connected at the second side (the bottom side) or at the edge of the substrate. Thus, no top mounted electrical interface is required from the substrate, which is advantageous with respect to miniaturization, light emission, etcetera.

The present invention relates to a light emitting diode (LED) module comprising a substrate, at least one LED chip mounted on one side of the substrate and an optical element covering the at least one LED chip.

A light emitting diode (LED) package comprising a LED chip mounted on top of a substrate and an optical lens covering the chip and substrate is described in for example the document U.S. Pat. No. 6,274,924. Such a package further comprises bond wires extending from the top of the chip and the substrate to metal leads of the LED package, which leads provide for electrical connection to control circuitry. The optical lens covering the substrate with the chip is adapted so that it also covers the bond wires extending from the chip and the substrate.

However, to minimize package cost, a LED package should be as small as possible. For this miniaturization of the package, it is necessary to minimize the diameter of the optical lens directly around the chip, and this is limited by the presence of the bond wires extending outwards the substrate. The bond wires also interfere with the light emission from the LED chip, which negatively affects the performance of the LED module.

Also, in order to achieve optical contact between the optical lens and the LED chip, an encapsulant is in general applied between the lens and the chip. However, the bond wires significantly limits the choice of encapsulant materials, and as a consequence, the maximum chip temperature and chip power becomes limited, which in turn restricts the performance of the LED module.

It is an object of the present invention to provide an improved LED module, which alleviates the problem in miniaturization and may be manufactured and packaged at a low cost.

This and other objects that will be evident from the following description are achieved by means of a LED module by way of introduction, wherein the substrate is provided with at least one via channel extending from the first side of the substrate to a second opposite side of the substrate, and wherein the via channel(s) is provided with conducting means for electrically connecting the at least one LED chip to a control circuit.

It should be noted that conductive via channels in a substrate is known per se, for example from the document U.S. Pat. No. 6,020,637. However, the invention is based on the understanding that by providing the substrate in a LED module with electrically conductive via channels, any electrical control circuit may be connected at the second side (the bottom side) or at the edge of the substrate. In other words, by the use of the via channels, the electrical connection interface towards control circuitry is placed at the bottom side or at the edge of the substrate, instead of at the top side of the substrate as in prior art. Thus, no electrical interfacing wire bonds to the control circuit is required on the top side of the substrate. This results in that the optical element may be placed closer to the LED chip(s), without interfering with any wire bonds or any other top mounted electrical interface, which means that the LED module may be realized in a smaller size. Also, multiple LED chips can be mounted to the substrate with maximal packing density.

The lack of wire bonds or similar top mounted electrical interface further means that high temperature resistant encapsulation and packaging can be used, so that the maximum chip temperature and chip power is not limited by the encapsulation material.

Another advantage in using via channels in the substrate for electrically connecting the LED chip(s) to the control circuit at the bottom or the edge of the substrate is that the electrical interface does not interfere with the light emission from the LED chip(s), which of course improves the performance of the LED module.

The LED module can further comprise a conductive metal pattern applied to the top side of the substrate, which pattern is arranged to provide electrical contact between connection pads on the LED chip(s) and the conducting means of the at least one via channel. In other words, the conductive metal pattern electrically connects the connections pads of the LED chip(s) and to the conducting means of the via channel(s). Thus, the connection pads of a LED chip do not have to be directly aligned to the via channels in the substrate.

In case a conducting or semi-conducting material like silicon is used in the substrate, the via channels in the substrate are electrically isolated from the substrate. The conducting means of the via channel(s) can comprise plural separate conductors. Thus, each via channel provides for plural electrical connections. An advantage with this is that only one single via channel is required to be able to individually drive one or more LED chip(s) (one single LED chip needs two electrical connections).

Preferably, the at least one via channel is arranged in the body of the substrate, i.e. apart from the edges of the substrate. Alternatively, the via channel(s) is arranged at the edge of the substrate. In this case, the channel is visible from the side of the substrate, which can be advantageous in connecting the substrate to the control circuit. Also, the manufacturing of the LED module can be facilitated.

According to one embodiment of the invention, the control circuit is mounted at the bottom end of the via channel(s) at the bottom side of the substrate. Preferably, the control circuit is connected to the conducting means of the via channel(s) by means of a solder connection. A heat sink is also mounted at the second side of the substrate, adjacent to the control circuit. Thus, a part (where via channel(s) exit) of the bottom side of the substrate is soldered to the control circuitry, and a part (where no via channel(s) exit) of the bottom side of the substrate is soldered to the heat sink.

In another embodiment, the substrate and the control circuit are mounted adjacent to each other on a heat sink. Thus, the bottom side of the substrate is soldered to a single body, i.e. the heat sink. The heat sink is further provided on the side facing the substrate and the control circuit with a conductive layer. The conductive layer serves to electrically connect the control circuit to the conducting means of the via channel(s) in the substrate.

In a further embodiment, the substrate is mounted on a heat sink, whereby the control circuit is arranged between the bottom side of the substrate and the heat sink. Thus, the electrical circuit may be directly soldered to the conductor means of the via channel(s) at the bottom side of the substrate.

Preferably, the at least one LED chip of the LED module is flip chip mounted. However, also non-flip chips can be used. These may for example be wire bonded to the substrate. In case wire bonds are used between LED chip(s) and substrate, there will be drawbacks in terms of choice of encapsulant. However, the optical element can still be positioned closer to the LED chip(s) compared to prior art solutions due to the use of vias in the substrate instead of wire bonds between the substrate and the interface board.

This and other aspects of the present invention will be described in more detail in the following, with reference to the appended figures showing presently preferred embodiments.

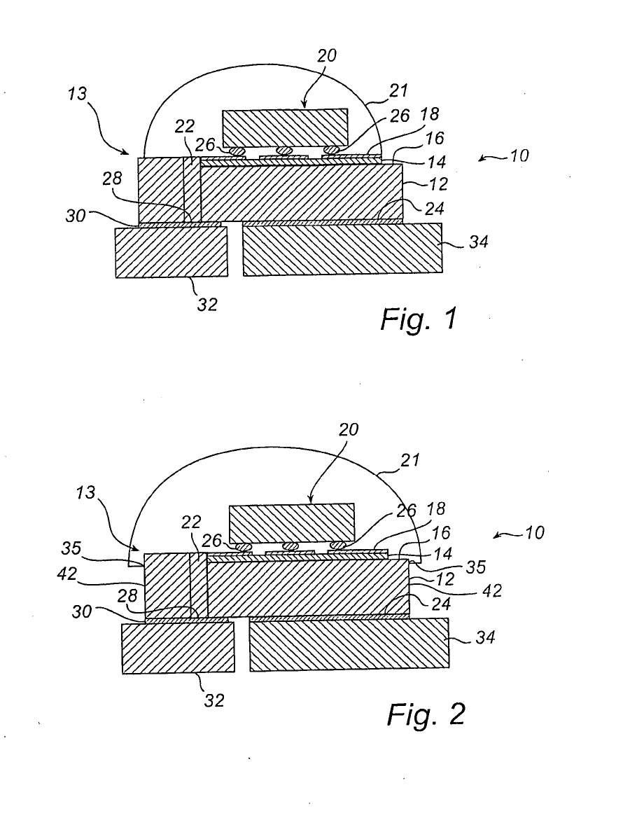

FIG. 1 is a schematic side view showing a LED module according to a first embodiment of the invention,

FIG. 2 is a schematic side view showing a modification of the LED module in FIG. 1,

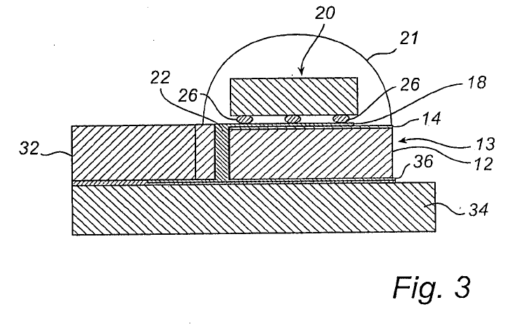

FIG. 3 is a schematic side view showing a LED module according to a second embodiment of the invention,

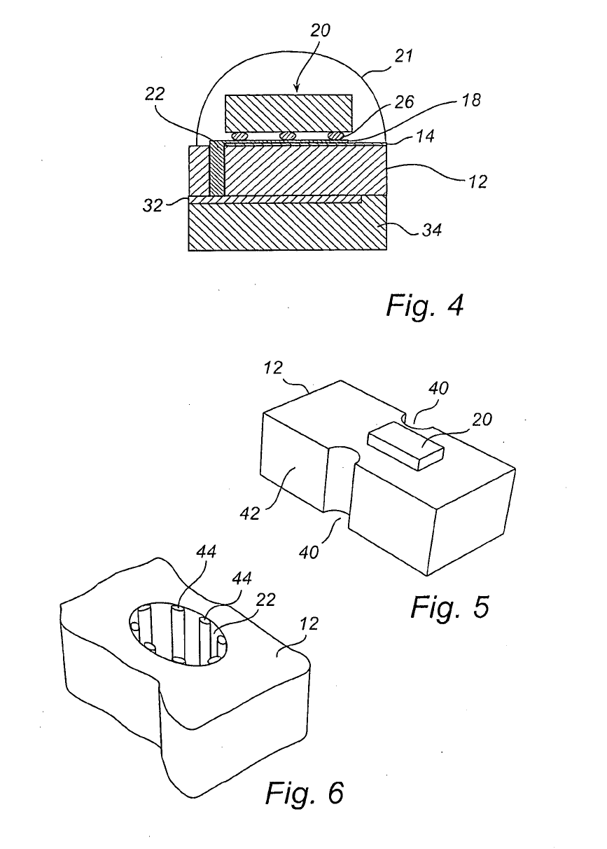

FIG. 4 is a schematic side view showing a LED module according to a third embodiment of the invention,

FIG. 5 is a schematic perspective view showing a substrate with via channels at the edge of the substrate, and

FIG. 6 is a schematic partial view showing a via hole.

In the figures, identical reference numerals have been used for corresponding elements of the LED module.

FIG. 1 shows a LED module 10 according to a first embodiment of the present invention. The LED module 10 comprises a substrate 12, for example a silicone substrate. The LED module 10 further comprises a dielectric layer 14, which is applied on the top side 16 of the substrate 12, and a metal pattern layer 18 applied on top of the dielectric layer 14. The substrate, the dielectric layer and the metal pattern layer constitute a submount 13 on which a LED chip 20 is mounted. The submount 13 with the LED chip 20 is covered by an optical element 21, for instance an optical lens or a collimator.

The substrate 12 is further provided with a via channel or via hole 22 extending in the body of the substrate from the top side 16 to the bottom side 24 of the substrate. In FIG. 1, the via hole 22 is filled with a conducting material, whereby the via hole functions as an electrical conductor between the top side 16 and the bottom side 24 of the substrate 12. In case of a conducting or semi-conducting substrate, the via hole, or at least the conductor in the via hole, must be isolated from the substrate.

The metal pattern 18 on top of the substrate 12 is so designed that the connection pads 26 of the chip 20 is in electrical connection with the via hole 22, even though the chip is not placed directly on top of the via hole.

A major part of the substrate 12 is soldered to a heat sink 34, while a small part at the bottom end 28 of the electrically conductive via hole 22 is in contact, by means of a solder connection 30, with an electrical control circuit 32 for controlling the LED chip 20. Also, as may be seen in FIG. 1, the control circuit is mounted essentially in level with, and adjacent to, the heat sink 34.

Thus, the via hole 22 provides for electrical connection between the LED chip 20 and the control circuit 32 so that during operation of the LED module, the LED chip can be controlled by the control circuit. Also, the lens 21 is positioned close to the LED chip 20 since there is not interfering top-mounted electrical interface (such as bond wires or the like) extending from the substrate.

An alternative positioning of the optical element is shown in FIG. 2. In FIG. 2, the optical element 21 extends to the edges 42 of the substrate 12. An advantage with this positioning of the optical element is that no side light from the LED chip 20 can escape via the seal/glue layer at the fixing point 35 between the optical element and the substrate, since the fixing point is below the plane of emission of the LED chip.

A second embodiment of the invention is shown in FIG. 3. In this embodiment, the bottom side of the substrate 12 is mounted only to the heat sink 34. The heat sink is further provided with a conductive layer 36 on the side of the heat sink facing the substrate. The heat sink 34 with the conductive layer 36 extends outside the substrate 12 so that the control circuit 32 can be mounted on top of the heat sink next to the substrate 12 as shown in FIG. 3. Thus, the control circuit 32 is mounted essentially in level with, and adjacent to, the substrate 12. The conductive layer 36 enables electrical connection between the control circuit 32 and the via hole 22.

Thus, the via hole 22, together with the conductive layer 36, in turn, provides for electrical connection between the LED chip 20 and the control circuit 32 so that during operation of the LED module, the LED chip can be controlled by the control circuit. Also, as above, the lens 21 can be positioned close to the LED chip 20 since there is no interfering top-mounted electrical interface (such as bond wires or the like) extending from the substrate.

A third embodiment of the invention is shown in FIG. 4. In this embodiment, the control circuit 32 is arranged between the substrate 12 and the heat sink 34. Thus, the control circuit 32 connects at the bottom side of the substrate 12 to the LED chip 20 on top of the substrate by means of the conducting means of the via hole 22, whereby no top mounted electrical interface is necessary. The control circuit 32 is preferably realized by a ceramic substrate. This configuration allows high thermal loads.

An alternative positioning of the via channel(s) is shown in FIG. 5. In FIG. 5, via channels 40 are arranged at the edge 42 of the substrate 12. This can facilitate the connection to control circuitry and the manufacturing of the LED module.

It should be noted that even though only one LED chip and one via hole/via channel is shown in the above FIGS. 1-4 (for the sake of clarity), it is envisaged that the LED module can comprise a plurality of LED chips and via holes/channels. Typically, to drive each LED chip individually, two electrical connections are required. Also, for multiple LED chips connected in series, two connections are required for each series. In case filled via holes are used as described above, one via hole is required for each connection, Thus, to individually drive one LED chip, or to drive a series of LED chips, two filled via holes are needed. As an alternative to the filled via holes, the sidewalls of a via hole may be coated with plural conductors 44, see FIG. 6. In this case, one single via hole can provide plural electrical connections to the LED chip(s). As indicated in FIG. 6, the via hole 22 may in this case have an elongated cross section.

It should also be noted that the electrical control circuit can comprise an interface board, such as a printed circuit board, flex substrate, thin flex substrate, etc., on which one or several components are arranged, realizing the control electronics.

The invention is not limited to the embodiments described above. Those skilled in the art will recognize that variations and modifications can be made without departing from the scope of the invention as claimed in the accompanying claims. For example, even though the LED chip in the above figures is flip chip mounted, also non-flip chips can be used.

Also, the aspect of via channels at the edge of the substrate may be exercised in any embodiment shown above.

Further, the aspect of having the optical element attached to the edge of the substrate, thus covering the whole top side of the substrate and the LED chip(s), may be exercised in other embodiments than the one shown in FIG. 2.

1. A LED module (10), comprising:
a substrate (12),
at least one LED chip (20) mounted on a first side of said substrate, and
an optical element (21) covering said at least one LED chip (20),
said substrate (12) being provided with at least one via channel (22, 40) extending from the first side of the substrate to a second opposite side of the substrate, said via channel(s) being provided with conducting means for electrically connecting said at least one LED chip (20) to a control circuit (32).

2. A LED module according to claim 1, further comprising a conductive metal pattern (18) applied to the first side of said substrate (12), which pattern is arranged to provide electrical contact between connection pads (26) on the LED chip(s) (20) and the conducting means of the at least one via channel (22, 40).

3. A LED module according to claim 1, wherein said at least one via channel (22) is electrically isolated from said substrate (12).

4. A LED module according to claim 1, wherein said conducting means comprises plural conductors (44).

5. A LED module according to claim 1, wherein said at least one via channel (40) is arranged at an edge (42) of the substrate (12) between said first and second side of said substrate (12).

6. A LED module according to claim 1, wherein the control circuit (32) is mounted at the via channel(s) (22, 40) at the second side of the substrate (12), and wherein a heat sink (34) is mounted at the second side of the substrate adjacent to the control circuit (32).

7. A LED module according to claim 1, wherein the substrate (12) and the control circuit (32) are mounted adjacent to each other on a heat sink (34), said heat sink being provided on the side facing the substrate and the control circuit with a conductive layer (36) for electrically connecting the control circuit (32) to the conducting means of the via channel(s) (22, 40) of the substrate.

8. A LED module according to claim 1, wherein the substrate (12) is mounted on a heat sink (34), and wherein the control circuit (32) is arranged between said heat sink (34) and said substrate (12).

9. A LED module according to claim 1, wherein said LED chip is flip chip mounted.
